(19) United States
(12) Patent Application Publication
(10) Pub. No.: US 2026/0221210 A1
(43) Pub. Date: Jul. 30, 2026

(54) Scan Clocking

(71) Applicant: Texas Instruments Incorporated, Dallas, TX (US)

(72) Inventor: Devanathan Varadarajan, Allen, TX (US)

(21) Appl. No.: 19/373,120

(22) Filed: Oct. 29, 2025

Related U.S. Application Data
(60) Provisional application No. 63/749,993, filed on Jan. 27, 2025.

(51) Int. Cl. G11C 29/12; G11C 29/14; G11C 29/32

(52) U.S. Cl. CPC G11C 29/12015; G11C 29/14; G11C 29/32; G11C 2029/3202

(57) ABSTRACT

A method for performing a scan-based logic built-in self-test is disclosed herein. The method includes writing a first portion of a test sequence into a first subset storage elements on clock pulses of a first clock signal that is at a first clock frequency, writing the first portion of the test sequence into a second subset storage elements on clock pulses of a second clock signal that is at a second clock frequency that is greater than the first clock frequency, writing the first portion of the test sequence into a third subset of storage elements on clock pulses of a third clock signal that is at a third clock frequency that is less than the second clock frequency, and performing, after writing the first portion of the test sequence to the third subset of the plurality of storage elements, a built-in-self-test using the first portion of the test sequence.

### CROSS-REFERENCE TO RELATED APPLICATIONS

This application claims priority to U.S. Provisional Patent Application No. 63/749,993, entitled “SCAN CLOCKING”, filed January 27, 2025, which is hereby incorporated by reference in its entirety

### FIELD

The present disclosure generally relates to integrated circuit devices and, more particularly, to integrated circuit devices having built-in self-test capability.

### BACKGROUND

Scan-based logic built-in self-test (LBIST) may be used to meet automotive safety integrity level (ASIL) fault coverage targets (e.g., as defined in ISO 26262). For example, LBIST may be used to meet the ASIL-D requirements. LBIST may be run, for example, at startup (key-in) of an automobile. In some examples, LBIST may be performed in a plurality of cores (e.g., all processing cores of an automobile), such as in parallel when starting the automobile to verify that no faults are detected. LBIST may also be run after startup of the automobile (e.g., when the automobile is being driven). In some examples, LBIST may be performed on a core during an idle time of such core.

Scan based tests may be susceptible to inductive noise issues caused by delay (e.g., from scan-enable wait cycles) between scan shift operations. Such inductive noise may result in power supply noise. Such power supply noise may be higher in smaller geometries as the power density is increased. Power supply noise may cause LBIST to fail, even when no functional fault is present.

### SUMMARY

A method for performing a scan-based logic built-in self-test is disclosed herein. The method includes writing a first portion of a test sequence into a first subset of a plurality of storage elements on clock pulses of a first clock signal that is at a first clock frequency. The method further includes writing the first portion of the test sequence into a second subset of the plurality of storage elements on clock pulses of a second clock signal that is at a second clock frequency, the second clock frequency being greater than the first clock frequency. The method further includes writing the first portion of the test sequence into a third subset of the plurality of storage elements on clock pulses of a third clock signal that is at a third clock frequency, the third clock frequency being less than the second clock frequency. The method further includes performing, after writing the first portion of the test sequence to the third subset of the plurality of storage elements, a built-in-self-test using the first portion of the test sequence.

Also disclosed herein is a method for performing a scan-based logic built-in self-test. The method includes writing a test sequence into a first plurality of storage elements on clock pulses of a first clock signal at a first frequency. The method further includes producing a second clock signal based on the first clock signal, the second clock signal having a second frequency that is greater than the first frequency. The method further includes writing the test sequence into a second plurality of storage elements on clock pulses of the second clock signal. The method further includes producing a third clock signal based on the first clock signal, the third clock signal having a third frequency that is less than the second frequency. The method further includes writing the test sequence into a third plurality of storage elements on clock pulses of the third clock signal. The method further includes performing a built-in-self-test using the test sequence in the third plurality of storage elements.

Also disclosed herein is a device for performing a scan-based logic built-in self-test. The device includes a clock circuit configurable to output a clock signal, a first storage element in communication with the clock circuit, a logic circuit in communication with the clock circuit and configurable to read data from the first storage element to perform a built-in-self-test, and a controller in communication with the clock circuit, the first storage element, and the logic circuit. The controller is configurable to instruct the clock circuit to output the clock signal at a first frequency, write a first portion of a test sequence to the first storage element on clock pulses of the clock signal at the first frequency, and instruct the clock circuit to output the clock signal at a second frequency. The controller is further configurable to write a second portion of the test sequence to the first storage element on clock pulses of the clock signal at the second frequency, the second frequency being greater than the first frequency, instruct the clock circuit to output the clock signal at a third frequency, write a third portion of the test sequence to the first storage element on clock pulses of the clock signal at the third frequency, the third frequency being less than the second frequency, and enable the logic circuit to read one of the first, second, or third portions of the test sequence from the first storage element to perform the built-in-self-test.

The foregoing features and elements may be combined in any combination, without exclusivity, unless expressly indicated herein otherwise. These features and elements as well as the operation of the disclosed examples will become more apparent in light of the following description and accompanying drawings.

### BRIEF DESCRIPTION OF THE DRAWINGS

Reference will now be made to the accompanying drawings, which are not necessarily drawn to scale. While the drawings illustrate various examples employing the principles described herein, the drawings do not limit the scope of the claims.

FIG. 1 illustrates a perspective view of an automobile including one or more controllers, in accordance with various examples.

FIGS. 2A-2C illustrate block diagrams of a system for testing a controller using a scan-based logic built-in self-test, in accordance with various examples.

FIG. 3 illustrates a flow chart of a finite state machine for performing a scan-based logic built-in self-test, in accordance with various examples.

FIG. 4 illustrates a timing diagram of a system performing a scan-based logic built-in self-test, in accordance with the finite state machine of FIG. 3 and the various examples associated therewith.

FIG. 5 illustrates a timing diagram of a system performing a scan-based logic built-in self-test, in accordance with the finite state machine of FIG. 3 and the various examples associated therewith.

FIG. 6 illustrates a flow chart of a method for performing a scan-based logic built-in self-test, in accordance with various examples.

FIG. 7 illustrates a flow chart of a method for performing a scan-based logic built-in self-test, in accordance with various examples.

FIG. 8 illustrates a flow chart of a method for performing a scan-based logic built-in self-test, in accordance with various examples.

### DETAILED DESCRIPTION

The following detailed description is presented for purposes of illustration and not of limitation. Benefits, advantages, and/or solutions to problems may be described with reference to various examples. The detailed description makes use of the various examples and refers to the accompanying drawings which illustrate the various examples described herein. The drawings, descriptions, and examples are described in sufficient detail to practice the disclosure. It is understood that connecting lines shown in the various drawings are intended to represent example functional relationships and/or physical couplings between various elements, but that other relationships and/or couplings are possible while remaining within the scope of the present disclosure. It will further be appreciated that the various drawings may not be drawn to scale in order to simplify and clarify the detailed description herein. Furthermore, it is understood that the descriptions and examples contained herein may permit the practice other examples using logical, chemical, and/or mechanical changes without departing from the spirit and scope of this disclosure. For example, the steps recited in method and process descriptions may be executed in a different order, additional process steps may be added, and/or process steps may be removed while remaining within the scope of the present disclosure.

Any reference to singular items and/or examples includes plural items and/or examples and any reference to more than one item and/or example may include a singular item and/or example. Similarly, references to “a”, “an”, or “the” may include one or more of the referenced items, unless stated otherwise. Any reference to connected, coupled, fixed, attached, or the similar words and/or phrases may include partial, full, temporary, removable, permanent, or the other connection options. Any reference to contact, or similar phrase, may include minimal contact or reduced contact. All ranges used herein may include both the upper and lower values of the ranges, including ratio limits, that are disclosed herein. Stated values may include at least the variation that is expected within the field in which the present disclosure is practiced and as would be understood and accepted to include values that are within 10% of a stated value. Similarly, the use of “approximately”, “about”, “substantially” or other similar term represents an amount that is close to the stated value and that may still achieve the stated, or desired, result and/or perform the stated, or desired, function and may refer to an amount that is within 10% of the stated value.

The accompanying drawings, and detailed description of the drawings, include reference numerals that may be repeated across multiple examples. The repetition of reference numerals is intended for simplicity and clarity of description and is not intended to form or dictate a relationship between different examples described herein. The examples and descriptions provided herein are intended to be illustrative and not limiting beyond the scope of the claims. The use of terms such as “on” and “over” may indicate that a first feature is formed directly contacting a second feature or may indicate a relationship of the first feature and the second feature without direct contact between the two, such as additional features being formed between the two. For example, “on” may be used to indicate direct contact between the two and “over” may be used to indicate either direct contact or being spaced apart by one or more intervening layers.

Spatially relative terms such as, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of discussion herein and are not intended to limit the orientation of the various components, systems, apparatuses, devices, or other features. It is therefore understood and appreciated that the use of the spatially relative terms to practice this disclosure in different orientations remains within the scope of the present disclosure.

Integrated circuit (IC) devices may include logic circuits, storage elements, and logic built-in self-test (LBIST) circuitry configurable to test the logic circuits. The LBIST circuitry may include an LBIST controller, multiple storage elements (e.g., flip-flops or flip-flop devices), and various logic circuits to be tested. During LBIST, one or more test sequences may be shifted into the storage elements to facilitate testing of the logic circuits. Specifically, the logic circuits may read data from and write data to the storage elements. In some examples, shifting the data into the storage elements may generate noise within the IC device (e.g., inductive noise or power supply noise) due to the number of active components. This power supply noise may cause the IC device to fail LBIST, even in the absence of a functional fault.

An IC device that fails LBIST due to power supply noise may be returned (or identified) as a faulty unit, even though the device may have no functional fault. In some examples, mission mode (e.g., in-field) and test mode (e.g., laboratory or automated test equipment (ATE) environments) may use different tuning parameters, often due to differences between the ATE board and the field or customer board. As such, a failure observed in the field (e.g., a failure in an in-system test such as in an automobile) may not be reproducible on the ATE. Additionally, debugging system-test failures in the field may be complex or impractical versus debugging in a controlled ATE environment.

Disclosed herein are systems and methods for minimizing inductive noise (e.g., power supply noise) during in-system LBIST. In some examples, the system may reduce inductive noise by ramping (e.g., up or down) a frequency of a clock signal (e.g., a scan clock) between scan shift operations, which may advantageously smoothen the noise. That is, the system may ramp-down the clock signal before running a capture mode to test the logic circuit. Ramping-down the clock signal may reduce inductive noise in the IC device before initiating the capture mode. After completing the capture mode, the system may ramp-up the clock signal to perform scan shift operations.

In some examples, the LBIST controller may implement a finite state machine (FSM) to control the clock signal (e.g., scan clock and/or capture clock) and counters used for different phases of the LBIST. For example, the counters may count the number of shift cycles, number of scan-enable cycles, number of dummy cycles before/after shift, number of capture cycles, etc. In some examples, ramp-up and ramp-down counters (e.g., RU and RD counters) may be implemented by the LBIST controller as part of the FSM. In some examples, the clock signal may be implemented using pulse-division, which may advantageously result in less complex clocking (e.g., no clocking distribution impact or overload of the LBIST FSM clock gates). In other examples, the clock signal may be implemented using pulse-stretching. For instance, a toggle flip-flop based frequency division may be used, which may advantageously result in a balanced 50% duty-cycle within a period.

For example, with balanced positive edge flip-flops and negative edge flip-flops, pulse-stretching may be beneficial as it balances power spikes. For examples with predominantly one of positive or negative edge flip-flops, the pulse-division approach may be preferred. In that regard, in some examples, pulse-division may be less complex to implement as only clock-gating enables to the functional clock are generated by the LBIST controller and not the actual clock. Pulse-stretching may be more complex from a clock distribution perspective as the actual stretched clock may be generated by the LBIST controller that may need to bypass the functional clock. Regardless, as disclosed herein, either pulse-division or pulse-stretching may be used and are within the scope of the present disclosure.

In some examples, the slope of the ramp-up and/or ramp-down (e.g., the number of silent cycles between pulses) may be programmable (e.g., using registers or by making ramp-up and ramp-down programmable). By allowing programmability of the slope of the ramp-up and ramp-down of the scan clock, some examples may advantageously allow for performing tuning to reduce power supply noise in the field.

Advantages of some examples may include providing a deterministic reduction in supply noise with negligible impact to test time as the ramp-up and ramp-down may be a small percentage of the overall scan shift cycles. Reduced power supply noise levels may advantageously enable faster scan shift frequency. Although no advantage is required for any particular example, some examples of the present disclosure provide a mechanism minimizing inductive noise during LBIST to noise induced failures and improve the LBIST.

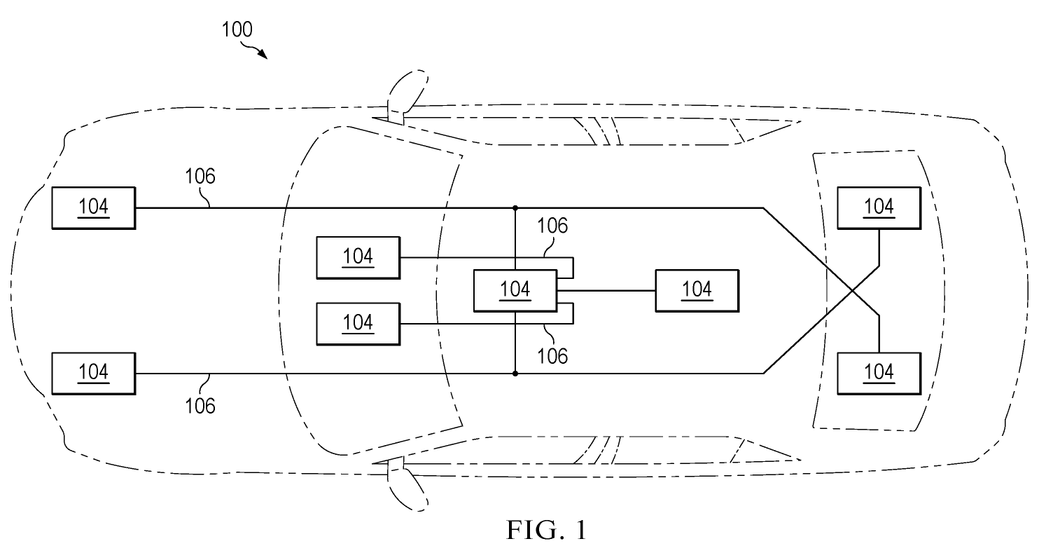

Referring now to FIG. 1, an automobile 100 is illustrated, in accordance with various aspects of the present disclosure. Automobile 100 includes a plurality of devices 104 and a communication bus 106 that connects the plurality of devices 104. In various examples, automobile 100 may be a vehicle such as a car, a truck, a van, a shuttle, a motorcycle, a bus, or the like. In various examples, the plurality of devices 104 may be configurable to control various functions of automobile 100. The various functions may include, lighting, climate control, windows, engine management, braking, steering, infotainment system, traction control, and instrument panels, among others. Each device 104 may be in communication with one or more of the other devices 104 via communication bus 106. In various examples, the plurality of devices 104 may be or include integrated circuit (IC) devices. In various examples, the plurality of devices 104 may be control area network (CAN) devices and communication bus 106 may be a CAN bus. As described below, one or more of devices 104 may be or include any of the components described herein performing the disclosed built-in-self-tests.

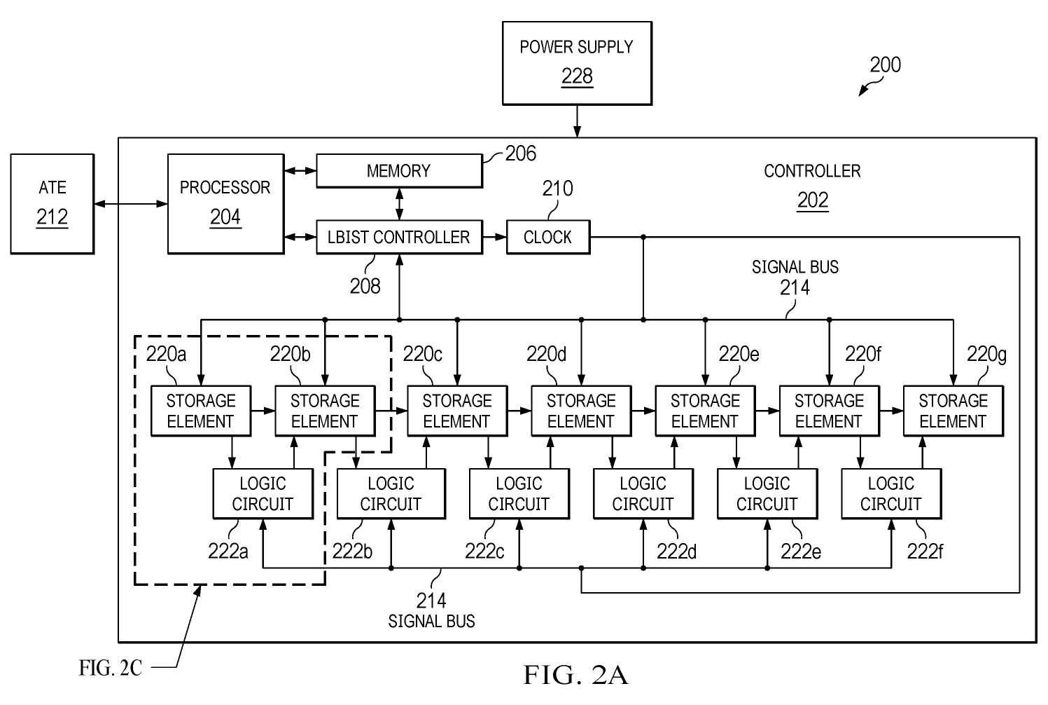

Referring now to FIGS. 2A-2C, a block diagram of a system 200 is illustrated, in accordance with various aspects of the present disclosure. System 200 includes a controller 202 and an automated test equipment (ATE) 212. In various examples, controller 202 may be an example of device 104 in FIG. 1. In other examples, controller 202 may be used in non-automotive applications. Controller 202 includes a processor 204, a memory 206, a logic built-in self-test (LBIST) controller 208, a clock circuit 210, a signal bus 214, a plurality of storage elements 220a, 220b, 220c, 220d, 220e, and 220f (collectively referred to as storage elements 220), a plurality of logic circuits 222a, 222b, 222c, 222d, 222e, and 222f (collectively referred to as logic circuits 222), and a power supply 228. Signal bus 214 may carry signals between LBIST controller 208, clock circuit 210, storage elements 220, and logic circuits 222. In some examples signal bus 214 may include multiple sub-busses or lines, such as a data bus, a clock bus, and a control bus. For example, LBIST controller 208 may provide data signals and a scan enable signal 209 and clock circuit 210 may provide a clock signal 211 over signal bus 214 to storage elements 220 and logic circuits 222. Power supply 228 provides power to controller 202 and the various components contained therein.

Processor 204 may control the general operation of controller 202. For instance, processor 204 may provide the processing capability to execute an operating system, programs, user and application interfaces, and/or any other functions of controller 202. Processor 204 may include one or more microprocessors, such as one or more general-purpose microprocessors, application-specific microprocessors (ASICs), or a combination of such processing components. Processor 204 may include one or more processors based on x86 or reduced instruction set computer (RISC) architectures, as well as dedicated graphics processors (GPU), image signal processors, digital signal processors (DSP), video processors, audio processors, and/or related chip sets. Processor 204 may include a number of same or different types of processing cores and may be implemented as a system on a chip (SOC) device.

Memory 206 includes computer-readable mediums that may store instructions to be executed by processor 204 and/or data for the operation of controller 202. Memory 206 may include one or more memory devices (e.g., dynamic random access memory (DRAM), synchronous DRAM (SDRAM) or internal memory, etc.). Memory 206 may further include one or more external memory devices (e.g., hard drive (HDD), solid state drive (SSD), flash memory, etc.). In various examples, memory 206 (e.g., random access memory (RAM)) may be used as operating memory by processor 204. That is, processor 204 may read data from and write data to the RAM during normal operations of controller 202. In some examples, memory 206 (e.g., read only memory (ROM)) may store operating instructions to be executed by processor 204. That is, processor 204 may read instructions from the ROM and execute those instructions. In some examples, the ROM may further store test instructions to be executed by LBIST controller 208. That is, LBIST controller 208 may read instructions from the ROM and execute those instructions to perform the logic built-in self-tests (LBISTs) of controller 202.

LBIST controller 208 may control the logic built-in self-test (LBIST) operation of controller 202. For instance, LBIST controller 208 may provide the processing capability to execute one or more logic built-in self-tests on startup of controller 202 (e.g., power on or initialization), or at other times as requested. In some examples, processor 230 may be implemented by one or more microprocessors, such as one or more general-purpose microprocessors, application-specific microprocessors (ASICs), or a combination of such processing components. LBIST controller 208 may be in communication with clock circuit 210, storage elements 220, and logic circuits 222 signal bus 214 via I/O 232. In various examples, LBIST controller 208 may send instructions to clock circuit 210 to generate a clock signal 211 for storage elements 220 and logic circuits 222. In various examples, LBIST controller 208 may provide a scan enable signal 209 to storage elements 220 and logic circuits 222 via signal bus 214. LBIST controller 208 may be in communication with processor 204 and/or memory 206. LBIST controller 208 may read instructions from memory 206 for performing logic built-in self-tests of controller 202. In various examples, timer 234 and/or counter 236 may be implemented using hardware within LBIST controller 208. In other examples, timer 234 and/or counter 236 may be implemented in software and executed by processor 230.

Clock circuit 210 may be in communication with LBIST controller 208, storage elements 220, and logic circuits 222. Clock circuit 210 may be configurable to provide a clock signal to storage elements 220 and logic circuits 222 via signal bus 214. In that regard, clock circuit 210 may be implemented using a system clock input, one or more flip-flops, one or more multiplexers, other components, or a combination thereof. In various examples, clock circuit 210 may output clock signal 211 in response to instructions from LBIST controller 208. In some examples, clock circuit 210 may use pulse-division to generate the clock signal from a system clock. For instance, clock circuit 210 may mask (or block) one or more clock pulses of the system clock to produce a clock signal at a target frequency. Accordingly, using pulse-division to generate clock signal 211 provides a less complex solution than other clock generation mechanisms. For example, clock circuit 210 may use a clock-gate based implementation to generate clock signal 211, including the ramp-up and ramp-down frequencies used during testing.

In other examples, clock circuit 210 may use pulse-stretching to generate the clock signal from the system clock. For instance, clock circuit 210 may change the level of the clock signal in response to the rising edge of a first pulse of the system clock and the falling edge of a second pulse of the system clock, generating one long pulse that spans the first and second pulses. Accordingly, using pulse-stretching to generate clock signal 211 provides a balanced signal having a 50% duty cycle within the clock period. For example, clock circuit 210 may use a flip-flop (e.g., toggle-flop) based implementation to generate clock signal 211 suing frequency division. Clock circuit 210 may further be configurable to block output of the system clock (e.g., provide no clock signal or hold the clock signal low).

ATE 212 is an external computer, machine, or equipment that may provide control signals, stream data, and/or test sequences to controller 202 and/or receive output from controller 202. In some examples, control signals, stream data, and/or test operations of controller 202 may be controlled by ATE 212. In some other examples, control signals, stream data, and/or test sequences may be processed by processor 204 and/or LBIST controller 208 before, or instead of, ATE 212. In various examples, ATE 212 may be interfaced to controller 202 by probing the integrated circuit (IC) die pads at the wafer level of controller 202, or by contacting package pins of controller 202 (not pictured).

Storage elements 220 are configurable to store data for use by logic circuits 222. In various examples, storage elements 220 may be or include one or more flip-flops, latches, other storage components, or a combination thereof. In various examples, storage elements 220 are configurable to enable shift operations (e.g., scan-in and scan-out) on clock pulses of a clock signal (e.g., from clock circuit 210). That is, LBIST controller 208 may assert a scan enable signal (e.g., set to ‘1’) that configures each storage element 220 to read data from an adjacent storage element 220, bypassing logic circuits 222. For instance, storage element 220c may read from storage element 220b and storage element 220d may read from storage element 220c. In this way, the shift operation may pass data sequentially into and through each storage element 220, beginning with storage element 220a. Likewise, the shift operation may read data from storage elements 220, beginning with storage element 220g. In various examples, both scan-in and scan-out of the shift operations may be performed simultaneously. For instance, on clock pulses of the clock signal, LBIST controller 208 may write new data to storage element 220a, data in storage elements 220 may shift through storage elements 220a-220g, and LBIST controller 208 may read out data from storage element 220g. Although FIG. 2 illustrates storage elements 220a-220g, it is understood that controller 202 may include any number of storage elements (e.g., more or less) without departing from the scope of the present disclosure.

Logic circuits 222 include the circuits that perform the functionality of controller 202. In various examples, logic circuits 222 may be one or more semiconductor components that are interconnected to perform a designed task such as arithmetic operations (e.g., addition, subtraction, multiplication), logic operations (e.g., AND, OR, NOT, etc.), and/or other operations for which controller 202 is designed. In various examples, logic circuits 222 are configurable to read data from and write data to storage elements 220. When LBIST controller 208 asserts the scan enable signal (e.g., set to ‘1’), logic circuits 222 may be disabled. In other words, logic circuits 222 may not be able to write data to storage elements 220. When LBIST controller 208 clears the scan enable signal (e.g., set to ‘0’), logic circuits 222 may be enabled. In other words, logic circuits may operate in response to clock pulses of the clock signal and write the results into the storage elements 220. This configuration allows LBIST controller 208 to test logic circuits 222 using test sequences (e.g., test patterns, known data). For instance, LBIST controller 208 may shift a test sequence into storage elements 220 when the scan enable signal is asserted, clear the scan enable signal, pulse the clock signal one or more times so that logic circuits 222 read and write data, assert the scan enable signal, and read the results from storage elements 220. Although FIG. 2 illustrates logic circuits 222a-222g, it is understood that controller 202 may include any number of logic circuits (e.g., more or less) without departing from the scope of the present disclosure.

As shown in FIG. 2C, storage element 220a and storage element 220b are implemented as flip-flop devices and logic circuit 222a is in communication with storage elements 220a and 220b. Storage elements 220a, 220b and logic circuit 222a are each connected to and in communication with signal bus 214. In that regard, scan enable signal 209 and clock signal 211 are both provided to storage elements 220a, 220b and logic circuit 222a by signal bus 214. Furthermore, data signal 240 is provided to storage element 220a by signal bus 214. Storage element 220a may output a data signal 242 to logic circuit 222a and storage element 220b. Logic circuit 222a may output a data signal 244 to storage element 220b, and storage element 220b may output a data signal 246 (e.g., to other storage element 220c). In other examples, data signal 246 may be output to signal bus 214. As described above, when scan enable signal is asserted (e.g., logic ‘1’) logic circuit 222a is disabled and storage elements 220 are configured for data shift operation. That is, storage element 220b may read and store data from data signal 242 (from storage element 220a) and ignore data from data signal 244 (from logic circuit 222a). Similarly, logic circuit 222a may not respond to clock signal 211. Conversely, when scan enable is cleared (e.g., logic ‘0’) logic circuit 222a may read and process data from data signal 242 and output data on data signal 244. Storage element 220b may read and store the data on data signal 244 (from logic circuit 222a) and ignore the data on data signal 242 (from storage element 220a). Storage element 222b outputs the data on data signal 246.

As will be described in greater detail below, LBIST controller 208 may be configurable to perform logic built-in self-tests (LBIST) of controller 202. For example, LBIST controller 208 may be configurable to use a finite state machine (FSM) to perform logic built-in self-tests of controller 202. In some examples, the logic built-in self-tests may be scan-based self-tests. That is, test sequences used during the self-test may be sequentially shifted (e.g., scanned or written) into storage elements 220. In other words, each portion (e.g., a bit, a byte, a word, etc.) of the test sequence (or data) may pass through each storage element 220 sequentially. For instance, LBIST controller 208 may write a first portion (or data unit) of the test sequence to storage element 220a on a first clock cycle, then, on a second clock cycle, the first portion may be written to storage element 220b and LBIST controller 208 may write a second portion (or data unit) of the test sequence to storage element 220a. Details of these operations are described in greater detail below.

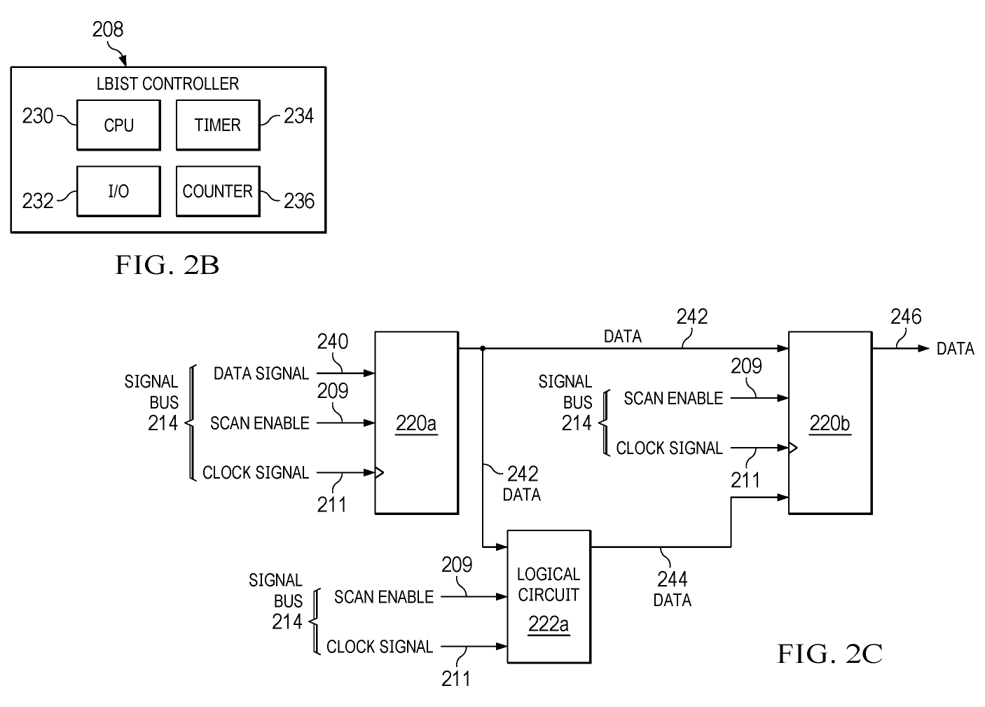

Referring now to FIGS. 3, 4, and 5, a state diagram for a finite state machine (FSM) 300, a first waveform 400, and a second waveform 500 are illustrated, in accordance with various aspects of the present disclosure. The operation of FSM 300 may be implemented by a controller (e.g., LBIST controller 208) that executes, or simulates, the behavior of FSM 300 by transitioning between states based on inputs and logic. In other examples, FSM 300 may be implemented using logic circuits that are external to LBIST controller 208 that transition between states of FSM 300 based on inputs and logic. FSM 300 is configurable to reduce noise while performing scan-in and scan-out operations (e.g., shift operations) of a scan-based self-test of a device (e.g., controller 202).

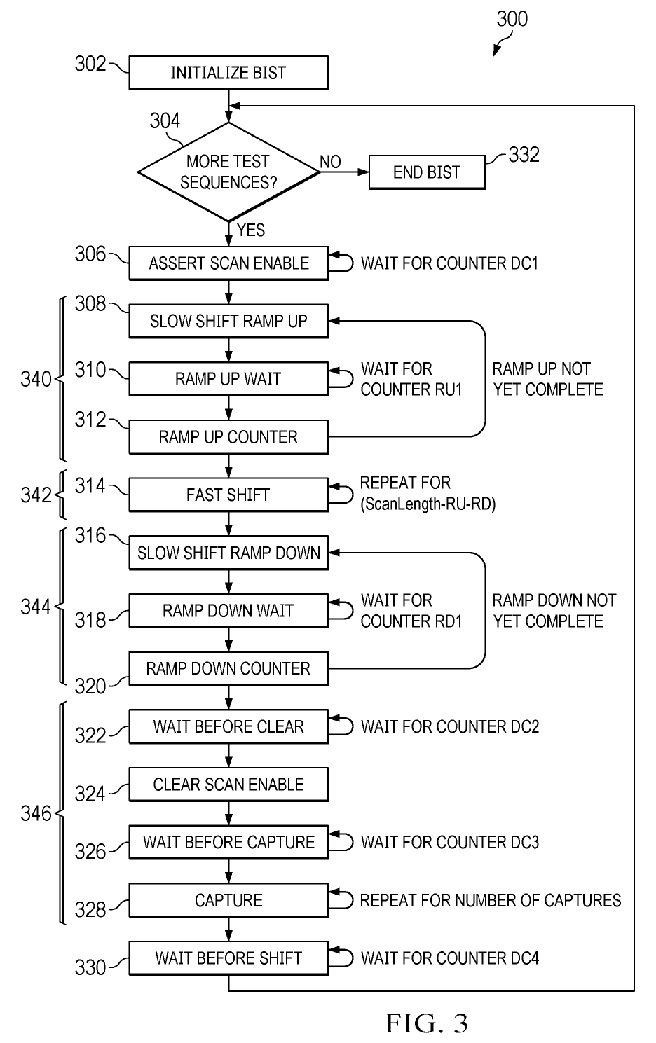

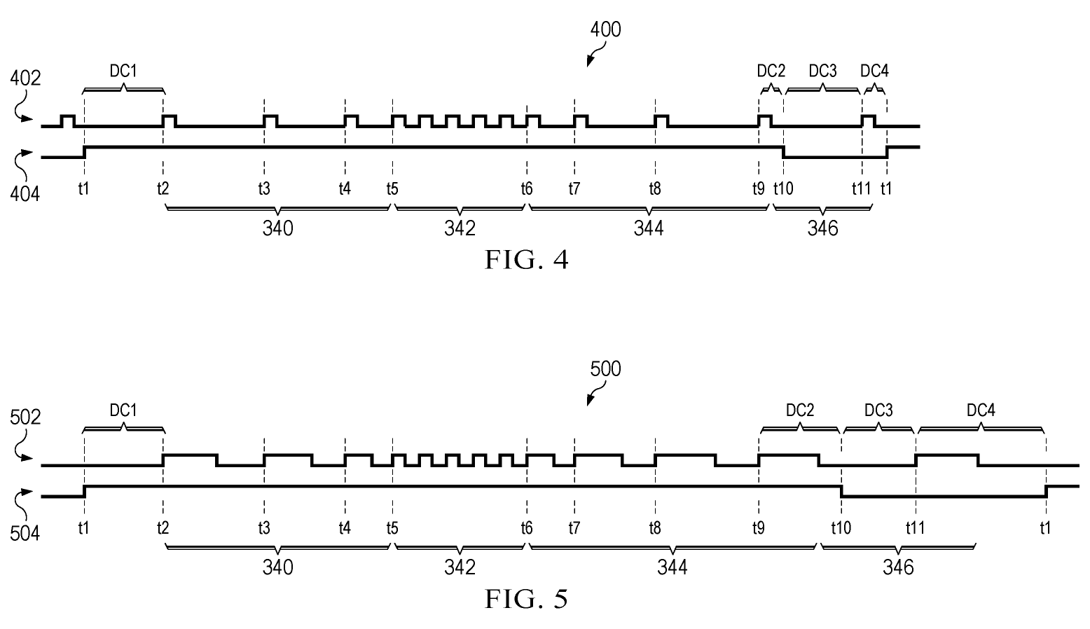

First and second waveforms 400, 500 may be example outputs of FSM 300. That is, first and second waveforms 400 and 500 may be generated as a result of LBIST controller 208 implementing FSM 300. FSM 300 is described below with reference to first and second waveforms 400, 500. In that regard, first waveform 400 of FIG. 4 illustrates an example implementation of FSM 300 using pulse-division to generate a clock signal. First waveform 400 includes a clock signal 402 and a scan enable signal 404. In some examples, clock signal 402 and scan enable signal 404 may be an examples clock signal 211 and scan enable signal 209, respectively, as described in FIG. 2. In other examples, as shown in FIG. 5, second waveform 500 illustrates an example implementation of FSM 300 using pulse-stretching to generate the clock signal. Second waveform 500 includes a clock signal 502 and a scan enable signal 504. In some examples, clock signal 502 and scan enable signal 504 may be an examples clock signal 211 and scan enable signal 209, respectively, as described in FIG. 2. In various examples, clock signal 402, 502 may be controlled by a clock circuit (e.g., clock circuit 210). In various examples, scan enable signal 404, 504 may be controlled by a controller (e.g., LBIST controller 208).

In some examples, scan enable signals 404 and 504 may be active-high, where asserting drives the signal high (e.g., logic ‘1’) and clearing drives the signal low (e.g., logic ‘0’). In other examples, scan enable signals 404 and 504 may be active-low, where asserting drives the signal low (e.g., logic ‘0’) and clearing drives the signal high (e.g., logic ‘1’). For simplicity, scan enable signals 404 and 504 are described below as being active-high. That is, when scan enable signal 404, 504 is asserted (e.g., logic ‘1’), the storage elements (e.g., storage elements 220) are enabled for shifting data and the logic circuits (e.g., logic circuits 222) are disabled. When scan enable is cleared (e.g., logic ‘0’), the storage elements are disabled for shifting data and the logic circuits are enabled.

In the below description of FIGS. 3-5, the controller uses various counters such as delay counters DC1-DC4, ramp-up counters RU1 and RU2, and ramp-down counters RD1 and RD2. Each counter may represent a value in time units, clock ticks, clock cycles, or another unit defining a time interval. In some examples, one or more counters may be replaced by a timer. In that regard, the counters may be implemented using hardware counters, software timers, or a combination thereof. For examples, the counters may be implemented in LBIST controller 208 using timer 234 and/or counter 236. Each counter may define a delay (or wait duration) that the controller may use to either hold FSM 300 in its current state before transitioning or to control clock signals 402 or 502 at a target frequency. For instance, in reference to FIG. 2, LBIST controller 208 may use the delay to instruct clock circuit 210 to output clock pulses at the target frequency.

In that regard, the controller implements FSM 300, including states 302-332, to minimize inductive noise during the LBIST to decrease, or eliminate, failures caused by power supply noise. As will be described below in further detail, FSM 300 includes a ramp-up phase 340 (including states 308-312), a fast shift phase 342 (including state 314), a ramp-down phase 344 (including states 316-320), and a capture phase 346 (including states 322-328). The controller shifts a test sequence into storage elements 220 during ramp-up phase 340, fast shift phase 342, and ramp-down phase 344 and tests the logic circuits during capture phase 346. Specifically, the controller may begin shifting the test sequence into storage elements 220 while increasing from a low clock pulse frequency to a high clock pulse frequency during ramp-up phase 340, continues shifting the test sequence into storage elements 220 at the high clock pulse frequency during fast shift phase 342, and finishes shifting the test sequence into storage elements 220 while decreasing from the high clock pulse frequency to the low clock pulse frequency during ramp-down phase 344. During capture phase 346, the controller may pulse the clock signal one or more times to test logic circuits 222. The controller may repeat this process for each test sequence of the LBIST. By reducing the clock pulse frequency (e.g., during ramp-up phase 340 and/or ramp-down phase 344) before performing the capture, FSM 300 minimizes inductive noise in controller 202 and improves overall reliability of the LBIST with little to no effect on the performance of the LBIST. In some examples, changing the clock signal directly from a low frequency to a high frequency, or vice versa, (e.g., no ramping up or ramping down phase) may result in additional inductive noise within the device. The additional noise may cause errors in the shift or capture operations. Therefore, the ramp-up and ramp-down of the clock signal minimizes inductive noise in the device.

As described herein, the clock pulse frequency (or clock signal frequency) is relative and may be device and mission dependent. Therefore, for clarity and ease of discussion, the relative language of low frequency and high frequency are used herein. This difference is illustrated by clock signals 402 and 502 in FIGS. 4 and 5 which show the low clock pulse frequency increasing to the high clock pulse frequency during ramp-up phase 340, the high clock pulse frequency during fast shift phase 342, and the high clock pulse frequency decreasing to the low clock pulse frequency during ramp-down phase 344.

Referring to FIG. 3, finite state machine (FSM) 300 may begin at state 302 (‘INITIALIZE BIST’) where the controller initializes FSM 300. In various examples, initializing FSM 300 may include selecting a self-test (or self-tests) to perform, retrieving test sequences to be used during the self-test, and/or clearing old data, among other operations. After the controller initializes FSM 300, the self-test is ready to be run, and the controller transitions FSM 300 to state 304.

In that regard, each self-test may include one or more test sequences that may be used during the self-test to detect faults in logic circuits (e.g., logic circuits 222). In some examples, the test sequence may be used to detect stuck-at faults. For instance, the test sequence may include an all-zeros pattern, where each storage element (e.g., storage elements 220) is loaded with logic ‘0’, and an all-ones pattern, where each scan cell is loaded with logic ‘1’. In other examples, the test sequence may be used to identify bridging faults. For instance, the test sequence may include walking-1 and walking-0 patterns, in which a single logic value propagates through the storage elements. In other examples, the test sequence may be used to detect coupling faults, such as using checkerboard and inverse checkerboard patterns, which alternate logic values. In other examples, the test sequence may be useful to detect other faults such as pseudo-random patterns generated by a linear feedback shift register (LFSR) or transition patterns may also be used to create 0-to-1 and 1-to-0 transitions for delay fault testing.

Furthermore, each test sequence may be divided into different portions (including one or more data units such as bits, bytes, words, etc.) such that a different portion may be introduced to the storage elements in a different phase of FSM 300. For instance, a first portion of the test sequence may be shifted into the storage elements during ramp-up phase 340, a second portion of the test sequence may be shifted into the storage elements during fast shift phase 342, and a third portion of the test sequence may be shifted into the storage elements during ramp-down phase 344. Other divisions of the test sequence are possible and are within the scope of this disclosure.

In state 304 (‘MORE TEST SEQUENCES’), the controller selects a test sequence (e.g., a data set or a test pattern) from the selected self-test to be used. In that regard, if FSM 300 transitioned from state 302 to state 304, the controller selects a first test sequence associated with the selected self-test. As described below, FSM 300 may already be running the selected self-test such that FSM 300 transitions to state 304 from state 330. In such examples, when FSM 300 transitions from state 330 to state 304, the controller selects a next test sequence (e.g., second, third, fourth test sequence, etc.) of the selected self-test, if any are available. After selecting a test sequence, the controller transitions FSM 300 to state 306. As shown, when there are no more test sequences available associated with the selected self-test, the controller transitions FSM 300 to state 332 where the selected self-test ends.

In state 306 (‘ASSERT SCAN ENABLE), the controller asserts a scan enable SE signal (e.g., scan enable signal 404, 504) and waits for a delay counter DC1, while keeping the scan enable signal asserted. As shown in FIGS. 4 and 5, scan enable signals 404 and 504 are asserted at time t1. The delay defined by delay counter DC1 provides time for the storage elements to be ready to receive and shift data for the self-test. If delay counter DC1 has not expired, the controller transitions FSM 300 to (or remains in or re-enters) state 306 and decrements delay counter DC1. Upon expiration of delay counter DC1, the controller transitions FSM 300 to state 308.

The controller now implements ramp-up phase 340 of FSM 300, including states 308, 310, and 312. During ramp-up phase 340, the controller shifts the test sequence into the storage elements (e.g., storage elements 220a-220g) while increasing the clock pulse frequency from a low frequency to a high frequency. As will be described in greater detail below, in state 308 the controller generates a clock pulse to shift the test sequence and in states 310 and 312 the controller waits. This is an iterative process that repeats, producing clock pulses at increasing frequencies until the clock pulse frequency is at the high frequency.

As shown in FIG. 4, in some examples, FSM 300 may use pulse-division to generate clock signal 402 that outputs a single clock pulse at times t2, t3, and t4 during ramp-up phase 340 of FSM 300. Specifically, at time t2 the controller implements states 308, 310, and 312 of FSM 300 to produce a first clock pulse and wait period. Similarly, for both times t3 and t4, the controller implements states 308-312 to produce each of a second and a third clock pulse and wait period, as an example. The iteration through states 308-312 results in the increased frequency of (e.g., decreased time between) each of the first, second, and third clock pulses. While three iterations are shown for ramp-up phase 340, there may may any number of iterations (e.g., clock pulses) within ramp-up phase 340 to transition from the low clock pulse frequency to the high clock pulse frequency.

Because pulse-division is used, each clock pulse is the same width while the time between each clock pulse changes. For instance, the controller may produce clock signal 402 by masking one or more clock pulses (or selectively using clock pulses) during ramp-up counter RU1. In some examples, the controller may instruct a clock circuit (e.g., clock circuit 210) to mask one or more system clock pulses to produce a clock signal having a first frequency, a second frequency, or any other frequency. As shown in FIG. 4, the first, second, and third clock pulses each have the same pulse width but have duty cycles that are different from each other. That is, the duration (or time high) of the first, second, and third clock pulses are the same but the percentage of time high for each of the first, second, and third clock pulses are different.

As shown in FIG. 5, in some examples, FSM 300 may use pulse-stretching to generate clock signal 502 that outputs a single clock pulse at times t2, t3, and t4 during ramp-up phase 340. Similar to FIG. 4, the controller produces first, second, and third clock pulses and wait periods at times t1, t2, and t3, respectively, by iterating over states 308-312. Because pulse-stretching is used, each clock pulse has a different width and the time between each pulse changes. For instance, the controller may produce clock signal 502 by stretching a clock pulse (e.g., maintain logic level ‘1’ or ‘0’) over multiple system clock cycles during ramp-up counter RU1. In some examples, the controller may instruct a clock circuit (e.g., clock circuit 210) to output logic ‘1’ on rising edge of a first system clock pulse and maintain logic ‘1’ until the falling edge of a second system clock pulse. The number of system clock cycles between the first system clock pulse and the second system clock pulse may produce a first frequency, a second frequency, or any other frequency. Therefore, the first, second, and third clock pulses each have different pulse width, but each have the same duty cycle. That is, the duration (or time high) of the first, second, and third clock pulses are different, but the percentage of time high for each of the first, second, and third clock pulses are the same.

Referring now back to FIG. 3, ramp-up phase 340, and the various iterations thereof, will be described with respect to states 308-312. As discussed above, these various states (e.g., states 308-312) may be used to generate the various clock pulses including transitioning from the low clock pulse frequency to the high clock pulse frequency occurring over ramp-up phase 340 (e.g., times t2-t4 of FIGS. 4 and 5).

In state 308 (‘SLOW SHIFT RAMP UP’), the controller pulses the clock signal to shift data through the storage elements and initializes ramp-up counters RU1 and/or RU2. That is, the controller instructs a clock circuit (e.g., clock circuit 210) to output a clock signal including a clock pulse. In response to the clock pulse, data is read from the last storage element (e.g., storage element 220g), all data shifts by one position, and new data (e.g., a portion of the test sequence) is written into the first storage element (e.g., storage element 220a). That is, the controller writes a different portion of the test sequence to the first storage element on each clock pulse. Additionally, on each clock pulse, each portion of the test sequence already in storage elements is shifted one position. For example, the controller may write a first portion of the test sequence to the first storage element on a first clock pulse. On each iteration of state 308 (e.g., each clock pulse), the controller writes a subsequent portion (e.g., a second, third, fourth, and so on) of the test sequence to the first storage element and the first portion shifts through the storage elements. Furthermore, the clock pulses ramp-up in frequency with each iteration of state 308. Therefore, the controller writes each portion of the test sequence to the first storage element, and the first portion of the test sequence shifts through the storage elements at a higher clock pulse frequency.

If FSM 300 transitioned to state 308 from state 306, the controller initializes ramp-up counters RU1 and RU2 to a first value corresponding to a first frequency. For instance, the wait duration defined by the first value may produce the first frequency. If FSM 300 transitioned to state 308 from state 312, the controller initializes ramp-up counter RU1 to the value of ramp-up counter RU2 which corresponds to a second frequency. After each iteration (e.g., each transition from state 312 to state 308), the value of ramp-up counter RU2 corresponds to a different, higher frequency than the previous iteration. This increase in frequency causes the time between clock pulses to decrease, as seen in FIGS. 4 and 5. After the clock pulse, the controller transitions FSM 300 to state 310.

In state 310 (‘RAMP UP WAIT’), the controller checks the value of ramp-up counter RU1 and determines which state to advance to. If ramp-up counter RU1 is not empty (e.g., a value greater than ‘0’), the controller decrements ramp-up counter RU1 and transitions FSM 300 to (or remains in or re-enters) state 310. If ramp-up counter RU1 is empty (e.g., a value of ‘0’), the controller transitions FSM 300 to state 312. In other words, the time spent in state 310 is about equal to the number of system clock cycles (or operations) that are used to decrement ramp-up counter RU1 and check its updated value. This causes the controller to wait in state 310 for a duration that is based on the initial value of ramp-up counter RU1. In some examples, a timer may be used instead of ramp-up counter RU1 to track the time spent in state 310.

In state 312 (‘RAMP UP’ COUNTER), the controller checks the value of ramp-up counter RU2 and determines which state to advance to. If ramp-up counter RU2 is not empty (e.g., a value greater than ‘0’), the controller decrements ramp-up counter RU2 and transitions FSM 300 to state 308. If ramp-up counter RU2 is empty (e.g., a value of ‘0’), the controller transitions FSM 300 to state 314. Using two ramp-up counters, RU1 and RU2, creates an outer loop (ramp-up counter RU2) and an inner loop (ramp-up counter RU1). The inner loop defines the frequency of clock pulses (e.g., the first and second frequencies) while the outer loop defines the number of frequencies the controller uses during ramp-up of the clock signal. In other words, the outer loop (RU2) defines the number of iterations of ramp-up phase 340 (e.g., states 308, 310, and 312) while the inner loop (RU1) defines the length of each iteration. During the ramp up, each iteration may be shorter than the previous iteration because ramp-up counter RU1 is initialized to the value of ramp-up counter RU2, which decrements with each iteration.

Upon ramp-up counter RU2 being empty (e.g., a value of ‘0’), the controller transitions FSM 300 to fast shift phase 342, including state 314. During fast shift phase 342, the controller shifts the majority of the test sequence into and through the storage elements while operating at the high clock pulse frequency. As will be described in greater detail below, in state 314 the controller generates a clock pulse to shift the test sequence. This is an iterative process that repeats until the test sequence is mostly written to the storage elements. In some examples, the test sequence may be considered mostly written when the portion of the test sequence remaining to be written is equal to the number of clock cycles to be used during ramp-down phase 344, as described in further detail below.

As shown in FIGS. 4 and 5, clock signals 402 and 502 output clock pulses at the high frequency beginning at time t5 during fast shift phase 342. Specifically, at time t5 the controller implements state 314 of FSM 300 to the clock pulses at the high frequency. In the examples of FIGS. 4 and 5, the clock pulses in fast shift phase 342 each have the same pulse width and duty cycle regardless of whether pulse-division or pulse-stretching is used. In other examples, there may be a difference in the characteristics of the clock pulses during fast shift phase 342 when using either pulse-division or pulse-stretching.

Referring now back to FIG. 3, fast shift phase 342, and the various iterations thereof, will be described with respect to state 314. As discussed above, this state (e.g., state 314) may be used to generate the various clock pulses at the high clock pulse frequency occurring over fast shift phase 342 (e.g., beginning at time t5 of FIGS. 4 and 5).

In state 314 (‘FAST SHIFT’), the controller pulses the clock signal to shift data through the storage elements. This operation occurs at the high frequency so that the data (e.g., test sequence) is shifted into the storage elements in a short period of time (e.g., shorter period of time than ramp-up phase 340 and/or ramp-down phase 344). Additionally, the controller may determine a remaining portion of the test sequence to be shifted into the storage elements and a number of clock cycles to be used in ramp-down phase 344. Generally, the majority of the test sequence may be shifted into the storage elements during the fast shift phase 342 (e.g., in state 314). For example, with respect to storage elements 220a-220g shown in FIG. 2, seven clock cycles may be used to shift the test sequence through storage elements 220. In such an example, the controller may produce five clock cycles while iterating in state 314. Whereas the controller may produce one clock cycle each while iterating in each of ramp-up phase 340 and ramp-down phase 344. That is, the controller spends majority of clock cycles in fast shift phase 342, as compared to ramp-up phase 340 and ramp-down phase 344.

In another example, involving twenty storage elements, twenty clock pulses may be used to shift the test sequence through twenty storage elements. In such an example, the controller may produce fourteen clock cycles while iterating in state 314. Therefore, the controller may produce three clock cycles each while iterating in ramp-up phase 340 and ramp-down phase 344, respectively. These are only examples and there may be any number of storage elements (e.g., storage elements 220) and both ramp-up and ramp-down phases 340, 344 may use any number of clock pulses to transition the clock pulse frequency such that fast shift phase 342 may use any number clock pulses.

As described above, shifting the test sequence into the storage elements at the high frequency (e.g., short period of time) may generate noise on the power supply but shifting the test sequence into the storage elements at the low frequency (e.g., low power supply noise) may take a long time. Ramping-down the clock frequency may reduce the power supply noise before performing the capture phase of the built-in self-test. Therefore, as described above, the controller may determine a remaining portion of the test sequence to be shifted into the storage elements and a number of clock cycles to be used in ramp-down phase 344. If the remaining portion of the test sequence is greater than the number of clock cycles to be used in ramp-down phase 344, the controller transitions FSM 300 to (or remains in or re-enters) state 314. If the remaining portion of the test sequence is equal to the number of clock cycles to be used in ramp-down phase 344, the controller transitions FSM 300 to state 316.

Upon the controller determining the remaining portion of test sequence is equal to the number clock cycles to be used in ramp-down phase 344, the controller transitions FSM 300 to ramp-down phase 344, including states 316, 318, and 320. During ramp-down phase 344, the controller shifts the test sequence into the storage elements while decreasing the clock signal frequency from the high frequency to the low frequency. As will be described in greater detail below, in state 316 the controller generates a clock pulse to shift the test sequence and in states 318 and 320 the controller waits. This is an iterative process that repeats, producing clock pulses at decreasing frequencies until the clock pulse frequency is at the low frequency.

As shown in FIG. 4, in some examples, clock signal 402 outputs a single clock pulse at times t6, t7, t8, and t9 using pulse-division during ramp-down phase 344. Specifically, at time t6 the controller implements states 316, 318, and 320 of FSM 300 to produce a first clock pulse and wait period. Similarly, for times t7, t8, and t9, the controller implements states 316-320 to produce each of a second, a third, and a fourth clock pulse and corresponding wait periods. The iteration through states 316-320 results in the decreased frequency (e.g., increased time between) each of the first, second, third, and fourth clock pulses. While four iterations are shown for ramp-down phase 344, there may may any number of iterations (e.g., clock pulses) within ramp-down phase 344 to transition from the high clock pulse frequency to the low clock pulse frequency.

Moreover, similar to ramp-up phase 340 described above, because pulse-division is used during ramp-down phase 344, each clock pulse is the same width while the time between each pulse changes. For instance, the controller may produce clock signal 402 by masking one or more clock pulses (or selectively using clock pulses) during ramp-down counter RD1. In some examples, the controller may instruct a clock circuit (e.g., clock circuit 210) to mask one or more system clock pulses to produce a clock signal having a first frequency, a second frequency, or any other frequency. As shown in FIG. 4, the first, second, third, and fourth clock pulses each have the same pulse width but have duty cycles that are different from each other. That is, the duration (or time high) of the first, second, third, and fourth clock pulses are the same but the percentage of time high for each of the first, second, third, and fourth clock pulses are different.

As shown in FIG. 5, in some examples, clock signal 502 outputs a single clock pulse at times t6, t7, t8, and t9 using pulse-stretching during ramp-down phase 344. Similar to FIG. 4, the controller produces first, second, third, and fourth clock pulses and wait periods at times t6, t7, t8, and t9, respectively, by iterating over states 316-320. Because pulse-stretching is used, each clock pulse has a different width and the time between each pulse changes. For instance, the controller may produce clock signal 502 by stretching a clock pulse (e.g., maintain logic level ‘1’ or ‘0’) over multiple system clock pulses during ramp-down counter RD1. In some examples, the controller may instruct a clock circuit (e.g., clock circuit 210) to output logic ‘1’ on rising edge of a first system clock pulse and maintain logic ‘1’ until the falling edge of a second system clock pulse. The number of system clock cycles between the first system clock pulse and the second system clock pulse may produce a first frequency, a second frequency, or any other frequency. Therefore, the first, second, third, and fourth clock pulses each have different pulse width, but each have the same duty cycle. That is, the duration (or time high) of the first, second, third, and fourth clock pulses are different, but the percentage of time high for each of the first, second, third, and fourth clock pulses are the same.

Referring now back to FIG. 3, ramp-down phase 344, and the various iterations thereof, will be described with respect to states 316-320. As discussed above, these various states (e.g., states 316-320) may be used to generate the various clock pulses including transitioning from the high clock pulse frequency to the low clock pulse frequency occurring over ramp-down phase 344 (e.g., times t6-t9 of FIGS. 4 and 5).

In state 316 (‘SLOW SHIFT RAMP DOWN’), the controller pulses the clock signal to shift data (e.g., the test sequence) through the storage elements and initializes ramp-down counters RD1 and/or RD2. If FSM 300 transitioned to state 316 from state 314, the controller initializes ramp-down counters RD1 and RD2 to a second value corresponding to a second frequency, or the ending frequency of the ramp-up (e.g., the high frequency). If FSM 300 transitioned to state 316 from state 320, the controller initializes ramp-down counter RD1 to the value of ramp-down counter RD2. After each iteration (e.g., each transition from state 320 to state 316), the value of ramp-down counter RD2 corresponds to a different, lower frequency than the previous iteration. This decrease in frequency causes the time between clock pulses to increase, as seen in FIGS. 4 and 5. After the clock pulses, the controller transitions FSM 300 to state 318.

In state 318 (‘RAMP DOWN WAIT’), the controller checks the value of ramp-down counter RD1 and determines which state to advance to. If ramp-down counter RD1 is not empty (e.g., a value greater than ‘0’), the controller decrements ramp-down counter RD1 and transitions FSM 300 to (or remains in or re-enters) state 318. If ramp-down counter RD1 is empty (e.g., a value of ‘0’), the controller transitions FSM 300 to state 320. In other words, the time spent in state 318 is about equal to the number of clock cycles (or operations) that are used to decrement ramp-down counter RD1 and check its updated value. This causes the controller to wait in state 318 for a duration that is based on the initial value of ramp-down counter RD1. In some examples, a timer may be used instead of ramp-down counter RD1 to track the time spent in state 318.

In state 320 (‘RAMP DOWN COUNTER’), the controller checks the value of ramp-down counter RD2 and determines which state to advance to. If ramp-down counter RD2 has not reached an end value (e.g., a predetermined value associated with the low frequency), the controller increments ramp-down counter RD2 and transitions FSM 300 to state 316. If ramp-down counter RD2 has reached the end value, the controller transitions FSM 300 to state 322. Similar to ramp-up counters RU1 and RU2, ramp-down counters RD1 and RD2 create an inner loop and an outer loop, respectively. In some examples, changing the clock signal directly from the high frequency to the low frequency may result in additional noise within the device. The additional noise may cause errors in the shift or capture operations. Such errors may not be reproducible because they are not functional failures.

Upon the controller determining ramp-down counter RD2 is empty, the controller transitions to capture phase 346 of FSM 300, including states 322, 324, 326, and 328. During capture phase 346, the test sequence is stored in the storage elements, and the controller clears the scan enable signal. As will be described in greater detail below, in state 322 the controller waits so that the data in storage elements is stable, in state 324 the controller sets the scan enable signal to ‘0’ (e.g., clears the signal), in state 326 the controller waits so that the change in the scan enable signal can propagate through the circuits and settle, and in state 328 the controller generates one or more clock pulses to perform one or more capture operations to test the logic circuits.

As shown in FIGS. 4 and 5, the controller waits for a delay of DC2, clears scan enable signal 404 at time t10, waits for a delay of DC3, clock signal 402 outputs a single clock pulse at time t11, and the controller waits a delay of DC4 during capture phase 346. While a single clock pulse at time t11 is shown, FSM 300 may output multiple clock pulses to test the logic circuits. In FIG. 4, clock signal 402 is implemented using pulse-division during capture phase 346. In FIG. 5, clock signal 502 is implemented using pulse-stretching, though pulse-division, or another scheme may be used during capture phase 346.

Referring now back to FIG. 3, capture phase 346, and the various iterations thereof, will be described with respect to states 322-328. As discussed above, these various states (e.g., states 322-328) may be used to generate the various signals, including clock pulses, for testing the logic circuits (e.g., logic circuits 222) (e.g., times t10 and t11 of FIGS. 4 and 5).

In state 322 (‘WAIT BEFORE CLEAR’), the controller waits for a delay counter DC2, while keeping the scan enable signal asserted. The delay provided by delay counter DC2 may ensure that the signals have stabilized and that the storage elements are ready to operate in the capture mode (e.g., functional mode), that the test sequence is properly stored in the storage elements, and/or to synchronize clock signal 402, 502 with a system clock. If delay counter DC2 has not expired, the controller transitions FSM 300 to (or remains in or re-enters) state 322 and decrements delay counter DC2. If delay counter DC2 has expired, the controller transitions FSM 300 to state 324.

In state 324 (‘CLEAR SCAN ENABLE’), the controller clears the scan enable signal. In various examples, the scan enable signal (e.g., scan enable signal 404, 504) may be cleared as either logic ‘1’ or logic ‘0’. Clearing the scan enable signal enables logic circuits (e.g., logic circuits 222 may read from / write to the storage elements 220) and disables storage elements (e.g., storage elements 220) for scan-in and scan-out operations (e.g., shift operations). As shown in FIGS. 4 and 5, scan enable signals 404 and 504 are cleared at time t10. After clearing the scan enable signal, the controller transitions FSM 300 to state 326.

In state 326 (‘WAIT BEFORE CAPTURE’), the controller waits for a delay counter DC3, while keeping the scan enable signal cleared. In various examples, delay counter DC3 correlates to noise generated by the power supply noise being at or below a threshold. In other examples, delay counter DC3 may allow the storage elements to transition from a shift mode to a capture mode, may minimize glitches or incorrect data capture, and/or allow signals to settle before performing the capture. If delay counter DC3 has not expired, the controller transitions FSM 300 to (or remains in or re-enters) state 326 and decrements delay counter DC3. If delay counter DC3 has expired, the controller transitions FSM 300 to state 328.

In state 328 (‘CAPTURE’), the controller pulses the clock signal for one or more capture cycles to test the logic circuits (e.g., logic circuits 222) using the test sequence stored in the storage elements. In some examples, the controller may pulse the clock signal a single time to cause the logic circuits to read data from the storage elements, perform an operation using the data, and write the results to the storage elements. In other examples, the controller may pulse the clock signal multiple times to cause the logic circuits to perform multiple reads, multiple operations on the read data, and multiple writes.

Referring now back to FIG. 3, the controller transitions FSM 300 from capture phase 346 to either continue running or end the LBIST, as described with respect to states 330, 304, and 332. As discussed above, LBIST may include multiple test sequences that are used as FSM 300 iterates through states 304-330. After all tests sequences have been used, the controller ends the LBIST.

In state 330 (‘WAIT BEFORE SHIFT’), the controller waits for a delay counter DC4, while keeping the scan enable signal cleared. As shown in FIGS. 4 and 5, delay counter DC4 occurs at time t11. Delay counter DC4 may be implemented for similar reasons as delay counters DC2 and DC3, described above. If delay counter DC4 has not expired, the controller transitions FSM 300 to (or remains in or re-enters) state 330 and decrements delay counter DC4. If delay counter DC4 has expired, the controller transitions FSM 300 to state 304.

Referring back to state 304, the controller determines whether there are more test sequences to run as part of the selected LBIST. If there are more test sequences, the controller transitions FSM 300 to state 306. If there are no more test sequences, the controller transitions FSM 300 to state 332.

In state 332 (‘END BIST’), the controller ends the selected self-test (e.g., LBIST). In various examples, ending the selected self-test may include outputting the results of the self-test for comparison or analysis.

Accordingly, disclosed herein are systems for performing a logic built-in self-test with minimized system noise. By reducing noise during the capture mode, these systems enhance the accuracy of self-test results, decreasing the likelihood of false error detections caused by noise rather than actual faults. The system includes a controller that is configurable to run a finite state machine (FSM) to shift data into a series of storage elements. The FSM is configurable to ramp-up (or increase) the clock frequency and ramp-down (or decrease) the clock frequency during the shift operations to reduce system noise. For example, the FSM ramps-up the clock frequency at the beginning of the shift operation and ramps down the clock frequency at the end of the shift operation, before performing the capture, to reduce system noise generated by the storage elements changing values.

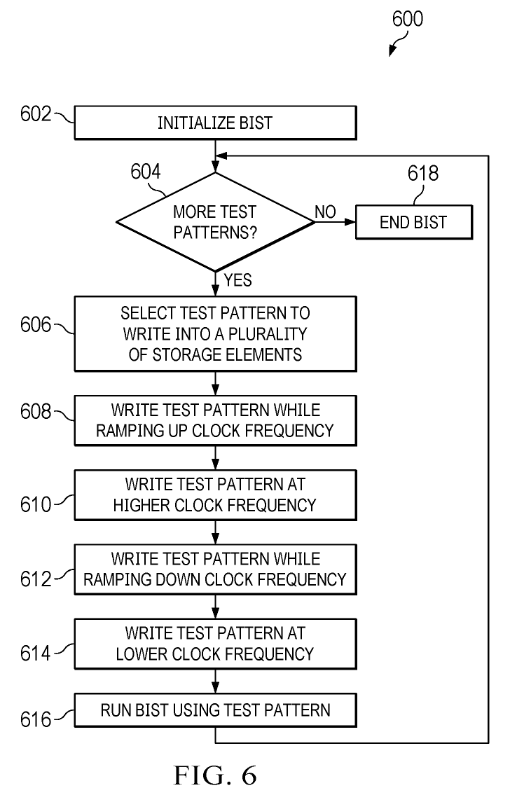

Referring now to FIG. 6, a flow diagram of a method 600 for performing a scan-based built-in self-test is illustrated, according to various aspects of the present disclosure. In various examples, method 600 may be performed by a processor (e.g., processor 204) or a controller (e.g., LBIST controller 208). In some examples, method 600 may be implemented by FSM 300, as described above. In other examples, method 600 may be implemented by other suitable control mechanisms, such as an event driven architecture. Additional processes can be provided before, during, and after method 600.

At step 602, a processor (e.g., processor 204 or LBIST controller 208) initializes a built-in self-test. At step 604, the processor determines whether there are more test patterns (or test sequences) to run. If the processor determines that there are more test patterns, method 600 proceeds to step 606. At step 606, the processor selects a test pattern to write into a plurality of storage elements. At step 608, the processor writes the test pattern while ramping-up the clock frequency. At step 610, the processor continues writing the test pattern at the higher clock frequency. At step 612, the processor continues writing the test pattern while ramping-down the clock frequency. At step 614, the processor continues writing the test pattern at the lower clock frequency. At step 616, the processor runs the built-in self-test using the test pattern stored in the plurality of storage elements. Method 600 then returns to step 604 to determine whether there are more test patterns to run. If the processor determines that there are no more test patterns, method 600 proceeds to step 618. At step 618, the built-in self-test is ended, and a result is provided by the processor.

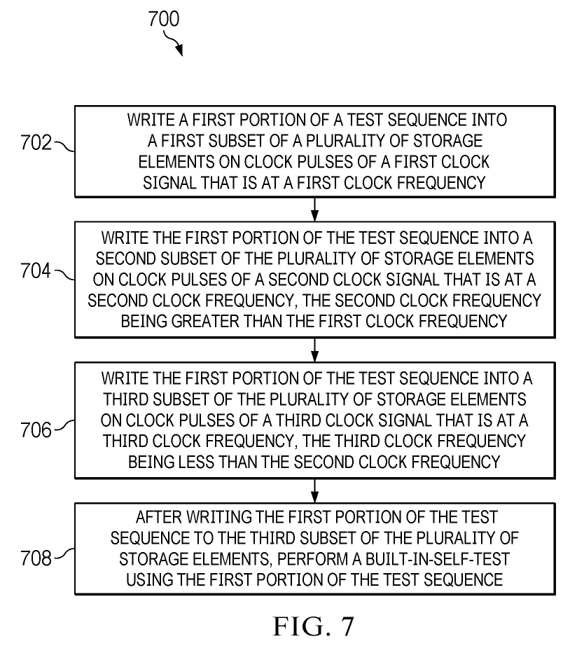

Referring now to FIG. 7, a flow diagram of a method 700 for performing a scan-based built-in self-test is illustrated, according to various aspects of the present disclosure. In various examples, method 700 may be performed by a processor (e.g., processor 204) or a controller (e.g., LBIST controller 208). In some examples, method 700 may be implemented by FSM 300, as described above. In other examples, method 700 may be implemented by other suitable control mechanisms. As described below, writing a portion of a test sequence may include pulsing a clock signal (e.g., clock signal 211). Additional processes can be provided before, during, and after method 700.

At step 702, a processor (e.g., LBIST controller 208) writes a first portion of a test sequence into a first subset of a plurality of storage elements (e.g., storage elements 220) on clock pulses of a first clock signal (e.g., clock signal 211) that is at a first clock frequency. In some examples, the first subset of storage elements may include one or more storage elements (e.g., storage element 220a). First clock frequency, in various examples, may be a clock frequency that is generated during ramp-up phase 340, during fast shift phase 342, or during ramp-down phase 344. For example, the processor may write the first portion of the test sequence to storage element 220a at a first frequency of ramp-up phase 340. Writing the first portion of the test sequence may include producing a value on signal bus 214 (e.g., data signal 240) when the first subset of the plurality of storage elements includes a first storage element in a scan chain (e.g., storage element 220a).

At step 704, the processor writes the first portion of the test sequence into a second subset of the plurality of storage elements on clock pulses of a second clock signal that is at a second clock frequency, the second clock frequency being greater than the first clock frequency. For example, the processor may write the first portion of the test sequence to storage element 220b at a second frequency of ramp-up phase 340. In other examples, the processor may write the first portion of the test sequence to storage element 220e at a second frequency of fast shift phase 342. Additional portions of the test sequence may be written to other subsets of the storage elements on clock pulses at the second frequency.

At step 706, the processor writes the first portion of the test sequence into a third subset of the plurality of storage elements on clock pulses of a third clock signal that is at a third clock frequency, the third clock frequency being less than the second clock frequency. For example, the processor may write the first portion of the test sequence to storage element 220f at a third frequency of ramp-down phase 344. Additional portions of the test sequence may be written to other subsets of the storage elements on clock pulses at the third frequency.

At step 708, after writing the first portion of the test sequence to the third subset of the plurality of storage elements, the processor performs a built-in self-test using the first portion of the test sequence. For example, the processor may clear scan enable signal 209 to activate logic circuits 222 and deactivate the scan mode of storage elements 220. The processor may then pulse clock signal 211 one or more times, assert scan enable signal 209, and shift the data out of storage elements 220 to determine whether controller 202 passed built-in self-test passed. The examples provided for description of method 700 are for illustrative and description purposes and are not intended to limit the scope of the claims.

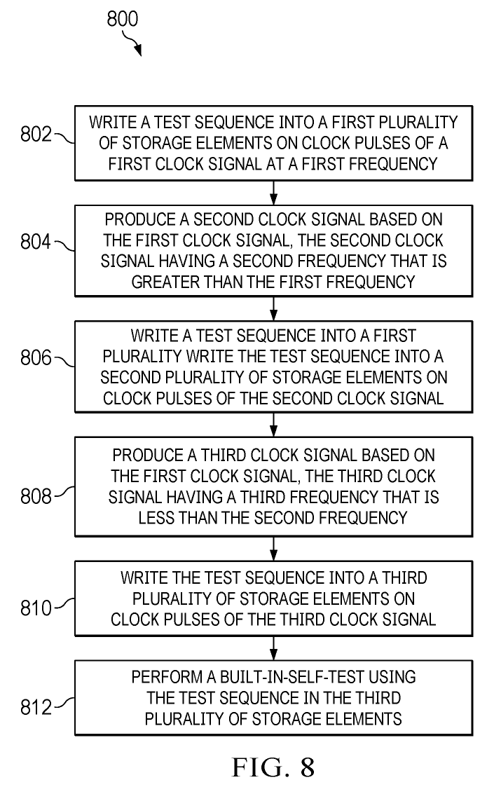

Referring now to FIG. 8, a flow diagram of a method 800 for performing a scan-based built-in self-test is illustrated, according to various aspects of the present disclosure. In various examples, method 800 may be performed by a processor (e.g., processor 204) or a controller (e.g., LBIST controller 208). In some examples, method 800 may be implemented by FSM 300, as described above. In other examples, method 800 may be implemented by other suitable control mechanisms. As described below, writing a portion of a test sequence may include pulsing a clock signal (e.g., clock signal 211). Additional processes can be provided before, during, and after method 800.

At step 802, a processor (e.g., LBIST controller 208) writes a test sequence into a first plurality of storage elements (e.g., storage elements 220) on clock pulses of a first clock signal (e.g., clock signal 211) at a first frequency. In some examples, the first subset of storage elements may include one or more storage elements (e.g., storage element 220a). First clock frequency, in various examples, may be a clock frequency that is generated during ramp-up phase 340, during fast shift phase 342, or during ramp-down phase 344. For example, the processor may write the test sequence to storage element 220a at a first frequency of ramp-up phase 340. Writing the test sequence may include producing a value on signal bus 214 (e.g., data signal 240) when the first subset of the plurality of storage elements includes a first storage element in a scan chain (e.g., storage element 220a). Furthermore, writing the test sequence may include writing one portion of the test sequence at a time to storage elements 220.

At step 804, the processor produces a second clock signal based on the first clock signal, the second clock signal having a second frequency that is greater than the first frequency. For example, the processor (e.g., LBIST controller 208) may instruct clock circuit 210 to produce clock signal 211 at a second frequency that is greater than the first frequency. In some examples, the first and second frequencies may be part of ramp-up phase 340. In other examples, first frequency may be part of ramp-up phase 340 and the second frequency may be part of fast shift phase 342.

At step 806, the processor writes the test sequence into a second plurality of storage elements on clock pulses of the second clock signal. For example, the processor may write the test sequence (or a portion thereof) to storage element 220c at the second frequency. The processor may further write the test sequence to other pluralities the storage elements on clock pulses of the second clock signal.

At step 808, the processor produces a third clock signal based on the first clock signal, the third clock signal having a third frequency that is less than the second frequency. For example, the processor (e.g., LBIST controller 208) may instruct clock circuit 210 to produce clock signal 211 at a third frequency that is less than the second frequency. In some examples, the second and third frequencies may be part of ramp-down phase 344. In other examples, second frequency may be part of fast shift phase 342 and the third frequency may be part of ramp-down phase 344.

At step 810, the processor writes the test sequence into a third plurality of storage elements on clock pulses of the third clock signal. For example, the processor may write the test sequence (or a portion thereof) to storage element 220f at the third frequency. The processor may further write the test sequence to other pluralities the storage elements on clock pulses of the third clock signal

At step 812, the processor performs a built-in-self-test using the test sequence in the third plurality of storage elements. For example, the processor may clear scan enable signal 209 to activate logic circuits 222 and deactivate the scan mode of storage elements 220. The processor may then pulse clock signal 211 one or more times, assert scan enable signal 209, and shift the data out of storage elements 220 to determine whether controller 202 passed built-in self-test passed. The examples provided for description of method 800 are for illustrative and description purposes and are not intended to limit the scope of the claims.

Accordingly, disclosed herein are systems and methods for minimizing power supply noise in IC devices during logic built-in self-test (LBIST). LBIST circuitry (e.g., an LBIST controller) may be configurable to shift a test sequence into storage elements (e.g., flip-flop device) for use by logic circuits during the LBIST. The LBIST circuitry may further be configurable to ramp-up and ramp-down the frequency of a clock signal to minimize inductive noise (e.g., power supply noise) in the IC device during the capture phase of the LBIST. For example, the LBIST circuitry may shift the test sequence into the storage elements at a high frequency to minimize the time used to shift in the test sequence. The LBIST circuitry may then ramp-down the clock signal to a low frequency for the final portions of the test sequence to reduce the inductive noise in the IC device. The capture phase may run at the low frequency, minimizing inductive noise and reducing, or eliminating, LBIST failures when no functional failures are present. The LBIST circuitry may then ramp-up the clock frequency to shift a new test sequence into the storage elements.

Finally, it should be understood that any of the above-described concepts can be used alone or in combination with any or all of the other above-described concepts. Although various examples have been disclosed and described, it is understood, recognized, and/or contemplated that certain modifications would come within the scope of this disclosure. Accordingly, the description is not intended to be exhaustive or to limit the principles described or illustrated herein to any precise form. Many modifications and variations are possible in light of the above teaching.

What is claimed is:

1. A method, comprising:
writing a first portion of a test sequence into a first subset of a plurality of storage elements on clock pulses of a first clock signal that is at a first clock frequency;
writing the first portion of the test sequence into a second subset of the plurality of storage elements on clock pulses of a second clock signal that is at a second clock frequency, the second clock frequency being greater than the first clock frequency;
writing the first portion of the test sequence into a third subset of the plurality of storage elements on clock pulses of a third clock signal that is at a third clock frequency, the third clock frequency being less than the second clock frequency; and
performing, after writing the first portion of the test sequence to the third subset of the plurality of storage elements, a built-in-self-test using the first portion of the test sequence.

2. The method of claim 1, further comprising:
writing the first portion of the test sequence into a fourth subset of the plurality of storage elements on clock pulses of a fourth clock signal at a fourth clock frequency, the fourth clock frequency being greater than the second clock frequency.

3. The method of claim 1, further comprising:
writing the first portion of the test sequence into a fourth subset of the plurality of storage elements on clock pulses of a fourth clock at a fourth clock frequency, the fourth clock frequency being less than the third clock frequency.

4. The method of claim 1, wherein writing the first portion of the test sequence into the second subset of the plurality of storage elements on clock pulses of the second clock signal includes writing a second portion of the test sequence into the first subset of the plurality of storage elements on clock pulses of the second clock signal, the second portion of the test sequence being different than the first portion; and
wherein performing the built-in-self-test further includes using the second portion of the test sequence.

5. The method of claim 1, wherein writing the first portion of the test sequence into the third subset of the plurality of storage elements on clock pulses of the third clock signal includes writing a second portion of the test sequence into the second subset of the plurality of storage elements on clock pulses of the third clock signal, the second portion of the test sequence being different than the first portion; and
wherein performing the built-in-self-test further includes using the second portion of the test sequence.

6. The method of claim 1, wherein writing the first portion of the test sequence to the third subset of the plurality of storage elements generates a power supply noise at a first level, the method further comprising:
waiting an amount of time after writing the first portion of the test sequence into the third subset of the plurality of storage elements, wherein the amount of time correlates to the power supply noise being at or below a second level that is less than the first level; and
performing the built-in-self-test after waiting the amount of time.

7. The method of claim 1, wherein clock cycles of the first clock signal at the first clock frequency has a first pulse width and clock cycles of the second clock signal at the second clock frequency has the first pulse width.

8. The method of claim 7, wherein clock cycles of the first clock signal at the first clock frequency has a first duty cycle and clock cycles of the second clock signal at the second clock frequency has a second duty cycle that is greater than the first duty cycle.

9. The method of claim 1, wherein clock cycles of the first clock signal at the first clock frequency has a first duty cycle and a first pulse width and clock cycles of the second clock signal at the second clock frequency has the first duty cycle and a second pulse width that is less than the first pulse width.

10. A method, comprising:
writing a test sequence into a first plurality of storage elements on clock pulses of a first clock signal at a first frequency;
producing a second clock signal based on the first clock signal, the second clock signal having a second frequency that is greater than the first frequency;
writing the test sequence into a second plurality of storage elements on clock pulses of the second clock signal;
producing a third clock signal based on the first clock signal, the third clock signal having a third frequency that is less than the second frequency;
writing the test sequence into a third plurality of storage elements on clock pulses of the third clock signal; and
performing a built-in-self-test using the test sequence in the third plurality of storage elements.

11. The method of claim 10, wherein producing the second clock signal includes masking one or more clock pulses of the first clock signal.

12. The method of claim 10, wherein producing the second clock signal includes not masking any clock pulse of the first clock signal.

13. The method of claim 10, wherein producing the second clock signal includes decreasing a pulse width of clock pulses of the first clock signal; and
wherein producing the third clock signal includes increasing a pulse width of clock pulses of the first clock signal.

14. The method of claim 10, wherein the first clock signal has a first duty cycle, the second clock signal has a second duty cycle, and the third clock signal has a third duty cycle, the first, second, and third duty cycles being different from each other.

15. The method of claim 10, wherein the first, second, and third clock signals each have the same duty cycle.

16. A device, comprising:
a clock circuit configurable to output a clock signal;
a first storage element coupled to the clock circuit;
a logic circuit coupled to the clock circuit and configurable to read data from the first storage element to perform a built-in-self-test; and
a controller coupled to the clock circuit, the first storage element, and the logic circuit, the controller configurable to:
instruct the clock circuit to output the clock signal at a first frequency;
write a first portion of a test sequence to the first storage element on clock pulses of the clock signal at the first frequency;
instruct the clock circuit to output the clock signal at a second frequency;
write a second portion of the test sequence to the first storage element on clock pulses of the clock signal at the second frequency, the second frequency being greater than the first frequency;
instruct the clock circuit to output the clock signal at a third frequency;
write a third portion of the test sequence to the first storage element on clock pulses of the clock signal at the third frequency, the third frequency being less than the second frequency; and
enable the logic circuit to read one of the first, second, or third portions of the test sequence from the first storage element to perform the built-in-self-test.

17. The device of claim 16, wherein instructing the clock circuit to output the clock signal at the first frequency includes masking, by the clock circuit, one or more clock pulses.

18. The device of claim 16, wherein instructing the clock circuit to output the clock signal at the second frequency includes decreasing a pulse width of clock pulses, by the clock circuit, to create the second frequency; and
wherein instructing the clock circuit to output the clock signal at the third frequency includes increasing a pulse width of clock pulses, by the clock circuit, to create the third frequency.

19. The device of claim 16, further comprising:
a power supply coupled to the first storage element, the logic circuit, and the controller;
wherein the controller is further configurable to:
wait an amount of time after writing the third portion of the test sequence into to the first storage element, wherein the amount of time correlates to noise generated by the power supply being at or below a threshold; and
enable the logic circuit to perform the built-in-self-test after waiting the amount of time.

20. The device of claim 16, wherein the first storage element includes a flip-flop device.
